(19) United States
(12) Patent Application Publication
(10) Pub. No.: US 2018/0059858 A1
(43) Pub. Date: Mar. 1, 2018

(54) TOUCH DISPLAY DEVICE

(71) Applicant: InnoLux Corporation, Jhu-Nan (TW)

(72) Inventor: Chia-Hao TSAI, Jhu-Nan (TW)

(21) Appl. No.: 15/674,299

(22) Filed: Aug. 10, 2017

(30) Foreign Application Priority Data
Aug. 31, 2016 (TW) 105128089

(51) Int. Cl. G06F 3/041; G06F 3/044; H01L 27/12

(52) U.S. Cl. CPC G06F 3/0416; G06F 3/044; H01L 27/323; G06F 2203/04108; H01L 27/1248

(57) ABSTRACT

A touch display device includes a touch panel. The touch panel includes a thin-film transistor (TFT) substrate, a light-emitting element, a transmission electrode, a sensing electrode, a cover layer and an encapsulation layer. The light-emitting element is disposed on the TFT substrate and has a first end electrode, a light-emitting layer and a second end electrode. The light-emitting layer is disposed between the first end electrode and the second end electrode. The transmission electrode and the sensing electrode are disposed on the light-emitting layer respectively. The cover layer is disposed opposite to the TFT substrate. The encapsulation layer is disposed between the second end electrode and the cover layer.

### CROSS REFERENCE TO RELATED APPLICATIONS

This Non-provisional application claims priority under 35 U.S.C. §119(a) on Patent Application No(s). 105128089 filed in Taiwan, Republic of China on Aug. 31, 2016, the entire contents of which are hereby incorporated by reference.

### BACKGROUND

### Technical Field

The present disclosure relates to a display device and, in particular, to a touch display device.

### Related Art

With the progress of technologies, various information devices, such as mobile phones, tablet computers, UMPC, and GPS, have been invented and introduced into our lives. Except the conventional input tools such as the keyboard or mouse, the intuitional touch input technology has been developed and becomes a popular operation method. Since the touch device has a humanized and intuitional input operation interface, the users of any ages can simply and directly use the finger or stylus to click or operation the information device.

One of the most popular touch control technologies is the 2D multi-touch technology (XY plane), which can precisely determine a touch position (e.g. touched by a finger) for generating the corresponding control function. In the 2D multi-touch technology, the conventional display device utilizes the mutual capacitance touch control technology, which is carried out by setting an additional touch panel. Accordingly, the additional processes and components for manufacturing the touch panel are needed for achieving the desired touch sensing function. Besides, the circuit for controlling the touch function and the circuit for controlling the display function are configured in different ICs. Thus, the costs for preparing the control ICs are increased.

In addition, the capacitance pressure sensing technology is adopted to sense the pressure force in the direction perpendicular to the display surface (Z axis direction), thereby generating a corresponding control function. In order to add the touch control function in the Z axis direction, the additional related components are needed, which will increase the manufacturing cost. Besides, the accuracy and preciseness of the touch control in the Z axis direction must be improved.

### SUMMARY

The present disclosure provides a touch display device, and the touch display device comprises a touch panel. The touch panel includes a thin-film transistor (TFT) substrate, a light-emitting element, a transmission electrode, a sensing electrode, a cover layer, and an encapsulation layer. The light-emitting element is disposed on the TFT substrate and has a first end electrode, a light-emitting layer and a second end electrode. The second end electrode is disposed on the first end electrode, and the light-emitting layer is disposed between the first end electrode and the second end electrode. The transmission electrode and the sensing electrode are disposed on the light-emitting layer respectively. The cover layer is disposed opposite to the TFT substrate. The encapsulation layer is disposed between the second end electrode and the cover layer.

In some embodiments, the touch control electrode of the touch display device can be integrated in the touch panel. The touch control electrode can be the transmission electrode, the sensing electrode or combination thereof. The sensing electrode is configured for sensing either or both of the 2D (two dimensional) signals and the 3D (three dimensional) signals. In addition, the circuit for controlling the touch function and the circuit for controlling the display function can be integrated in the same control IC by the mutual capacitance touch control technology. This design can reduce the processes for manufacturing the 2D or 3D touch panel and the cost of the control IC. Accordingly, the touch display device of this disclosure can have simplified manufacturing processes and less components as well as providing good accuracy and preciseness in touch control.

### BRIEF DESCRIPTION OF THE DRAWINGS

The embodiments will become more fully understood from the detailed description and accompanying drawings, which are given for illustration only, and thus are not limitative of the present disclosure, and wherein:

FIG. 1A is a sectional view showing a part of a touch display device according to an embodiment of the disclosure;

FIG. 1B is an equivalent circuit diagram of a pixel structure of the touch display device according to the embodiment of the disclosure;

FIG. 1C is a top view of the transmission electrode and the sensing electrode according to an aspect of the disclosure;

FIGS. 2A and 2B are sectional views showing parts of touch display devices according to different embodiments of the disclosure;

FIGS. 2C and 2D are schematic diagrams showing touch display devices according to different embodiments of the disclosure;

FIG. 2E is a top view of the transmission electrode and the horizontal sensing electrode according to another aspect of the disclosure;

FIGS. 3A to 3N are schematic diagrams showing touch display devices according to different embodiments of the disclosure;

FIGS. 4A and 4B are top views of the transmission electrode and the 3D sensing electrode according to different aspects of the disclosure;

FIGS. 4C to 4E are top views of the transmission electrode, the horizontal sensing electrode and the vertical sensing electrode according to different aspects of the disclosure;

FIGS. 5A to 5J are schematic diagrams showing touch display devices according to different embodiments of the disclosure;

FIGS. 6A to 6C are schematic diagrams showing reference electrodes of different aspects of the disclosure;

FIG. 7A is a schematic diagram of the control circuit of the touch display device of the disclosure when the 3D sensing electrode senses the 2D and 3D touch events in the situation of no touch event;

FIG. 7B is a schematic diagram of the control circuit of the touch display device of the disclosure when the 3D sensing electrode senses the 2D and 3D touch events in the situation of having 2D touch event;

FIG. 7C is a schematic diagram of the control circuit of the touch display device of the disclosure when the 3D sensing electrode senses the 2D and 3D touch events in the situation of having 3D touch event;

FIG. 7D is a schematic diagram showing the waveform of the touch signal in the situations of no touch event, having 2D touch event, and having 3D touch event;

FIG. 8A is a schematic diagram of the control circuit of the touch display device of the disclosure when the 2D and 3D touch events are sensed by different sensing electrodes in the situation of no touch event;

FIG. 8B is a schematic diagram of the control circuit of the touch display device of the disclosure when the 2D and 3D touch events are sensed by different sensing electrodes in the situation of having 2D touch event;

FIG. 8C is a schematic diagram showing the waveform of the touch signal in the situations of no touch event and having 2D touch event;

FIG. 9A is a schematic diagram of the control circuit of the touch display device of the disclosure when the 2D and 3D touch events are sensed by different sensing electrodes in the situation of no touch event;

FIG. 9B is a schematic diagram of the control circuit of the touch display device of the disclosure when the 2D and 3D touch events are sensed by different sensing electrodes in the situation of having a touch event in vertical direction;

FIG. 9C is a schematic diagram showing the waveform of the touch signal in the situations of no touch event and having a touch event in vertical direction; and

FIG. 10 is a schematic block diagram showing the touch detecting circuit and sensing electrode of the touch display device according to an embodiment of the disclosure.

### DETAILED DESCRIPTION OF THE DISCLOSURE

The embodiments of the disclosure will be apparent from the following detailed description, which proceeds with reference to the accompanying drawings, wherein the same references relate to the same elements. Moreover, the drawings of all implementation are schematic, and they do not mean the actual size and proportion. The terms of direction recited in the disclosure, for example up, down, left, right, front, or rear, only define the directions according to the accompanying drawings for the convenience of explanation but not for limitation. In addition, if one element is formed on, above, under, or below another element, these two elements can be directly contact with each other or not directly contact with each other but have an addition element disposed therebetween. The names of elements and the wording recited in the disclosure all have ordinary meanings in the art unless otherwise stated. Therefore, a person skilled in the art can unambiguously understand their meanings.

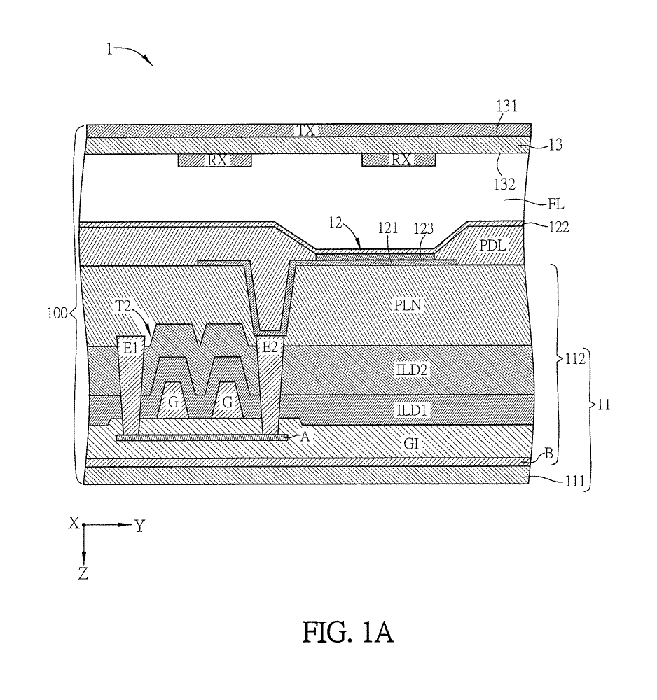

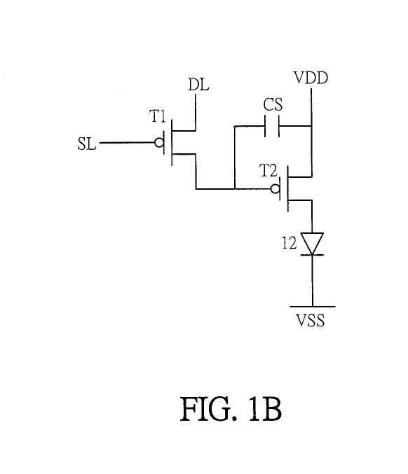

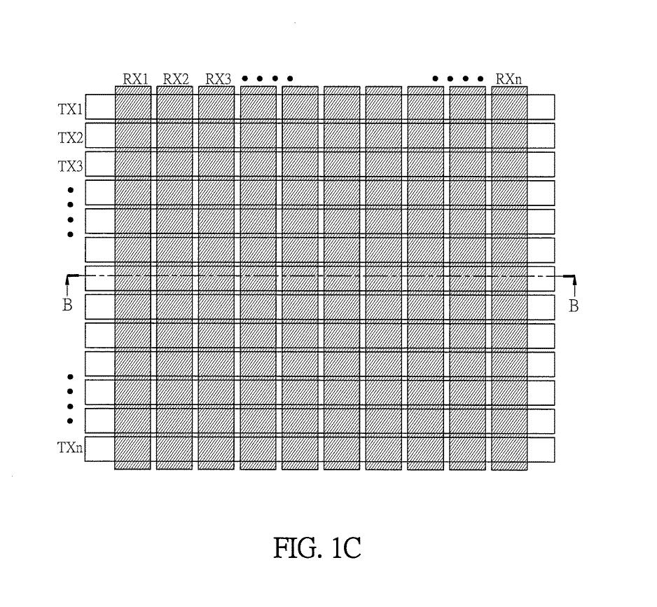

FIG. 1A is a sectional view showing a part of a touch display device 1 according to an embodiment of the disclosure. FIG. 1B is an equivalent circuit diagram of a pixel structure of the touch display device 1 according to the embodiment of the disclosure. FIG. 1C is a top view of the transmission electrode and the sensing electrode according to an aspect of the disclosure. To be noted, FIG. 1C is a top view of the touch display device 1 showing the relations of the transmission electrode TX and the sensing electrode RX, and the other layers are not shown. For example, FIG. 1C does not show the layers between the transmission electrode TX and the sensing electrode RX.

The touch display device 1 is an active matrix touch display device such as, for example, a smart phone, a tablet computer, an UMPC, a wearable device, or any other displayer with touch control function, and this disclosure is not limited.

As shown in FIG. 1A, the touch display device 1 includes a touch panel 100. The touch panel 100 includes a thin-film transistor (TFT) substrate 11, a light-emitting element 12, a transmission electrode TX, and a sensing electrode RX. In addition, the touch display device 1 of the embodiment further includes a pixel defining layer PDL, an encapsulation layer FL, and a cover layer 13. The touch panel can be an organic (e.g. organic light-emitting diode) touch panel or inorganic touch panel (e.g. light-emitting diode or quantum dot light-emitting diode), and the disclosure is not limited.

The TFT substrate 11 includes a substrate 111 and a TFT structure 112, which is disposed on the substrate 111. The substrate 111 can be a rigid plate or a flexible plate and be transparent or opaque. For example, the rigid plate is a glass, and the flexible plate is a flexible substrate made of, for example but not limited to, polyimide (PI) or polyethylene terephthalate (PET). In addition, the TFT structure 112 includes a plurality of transistor structures corresponding to the plurality of light-emitting elements 12. The transistor structures and the light-emitting elements 12 can form a plurality of pixel structures, which are arranged in a 2D array.

As shown in FIG. 1B, an equivalent circuit of a pixel structure is a 2T1C circuit, which includes a control transistor T1, a driving transistor T2, a storage capacitor CS, and a light-emitting element 12. The gate of the control transistor T1 is coupled to a scan line SL, a first end of the control transistor T1 is coupled to a data line DL, and a second end of the control transistor T1 is coupled to the gate of the driving transistor T2. The first end of the driving transistor T2 is coupled to a first power source VDD. Two ends of the storage capacitor CS are coupled to the gate and the first end of the driving transistor T2, respectively. The second end of the driving transistor T2 is coupled to the anode of the light-emitting element 12, and the cathode of the light-emitting element 12 is coupled to a second power source VSS. In this embodiment, the control transistor T1 and the driving transistor T2 are both PMOS transistors, for example. In other embodiments, the control transistor T1 and the driving transistor T2 can be both NMOS transistors, and this disclosure is not limited. In practice, the touch display device 1 includes a plurality of scan lines SL and a plurality of data lines DL, which are intersected with each other for defining the regions of the pixel structures. Besides, in some embodiments, the equivalent circuit of a pixel structure can be a 4T2C circuit, a 5T1C circuit, a 6T1C circuit, a 7T2C circuit, or other configurations, and this disclosure is not limited.

FIG. 1A shows the light-emitting element 12 and the driving transistor T2 of the TFT structure 112 of a pixel structure, and the control transistor T1 and the storage capacitor CS are not shown. Herein, the light-emitting element 12 is disposed on the TFT structure 112 and includes a first end electrode 121, a second end electrode 122, and a light-emitting layer 123. The first end electrode 121 is electrically connected with the second end of the driving transistor T2. The second end electrode 122 is disposed on the first end electrode 121, and the light-emitting layer 123 is disposed between the first end electrode 121 and the second end electrode 122. In this case, the light-emitting element 12 is a light emitting diode. When applying a forward bias to the light-emitting element 12, it can emit light.

In addition, the TFT structure 112 further includes a buffer layer B, a first dielectric layer ILD1, a second dielectric layer ILD2, and a planarization layer PLN. The buffer layer B is disposed on the substrate 111, and the driving transistor T2 is disposed on the buffer layer B. The driving transistor T2 includes a gate G, a gate insulation layer GI, a channel layer A, a first electrode E1, and a second electrode E2. In this case, the driving transistor T2 is a top-gate thin-film transistor. In other embodiments, the driving transistor T2 can be a bottom-gate thin-film transistor, and this disclosure is not limited.

The gate insulation layer GI is disposed on the buffer layer B, and the channel layer A is disposed on the gate insulation layer GI and located corresponding to the gate G. In this embodiment, the gate insulation layer GI is set to cover the channel layer A. The buffer layer B and the gate insulation layer GI can be made of an organic material (e.g. organic silicon oxygen compound) or inorganic material, such as silicon nitride, silicon oxide, silicon oxynitride, silicon carbide, alumina oxide, hafnium oxide, or multilayers of the above materials. In practice, the channel layer A can be an amorphous silicon layer, a polycrystalline silicon layer, or an oxide semiconductor layer. The above-mentioned oxide semiconductor layer may include a metal oxide, such as the oxide of indium, gallium, zinc, tin, or combinations thereof. In practice, the oxide semiconductor layer can be indium gallium zinc oxide (IGZO).

The first electrode E1 and the second electrode E2 are respectively disposed on the channel layer A, and one end of the first electrode E1 and one end of the second electrode E2 are contacted with the channel layer A. When the channel layer A of the driving transistor T2 is not conducted, the first electrode E1 and the second electrode E2 are electrically disconnected. The first electrode E1 and the second electrode E2 can be a single-layer structure or a multilayer structure made of metal (e.g. aluminum, copper, silver, molybdenum, or titanium) or alloy thereof. Besides, the wires for transmitting signals can be manufactured with the same process and the same layer as the first electrode E1 and the second electrode E2 (e.g. the data lines (not shown in FIG. 1A)).

The gate G is disposed on the gate insulation layer GI and located corresponding to the channel layer A. In this embodiment, the gate G is disposed on the channel layer A. The gate G can be a single-layer structure or a multilayer structure made of metal (e.g. aluminum, copper, silver, molybdenum, or titanium) or alloy thereof. Besides, the electrically connected wires for transmitting signals can be manufactured with the same process and the same layer as the gate G (e.g. the scan lines (not shown in FIG. 1A)). In addition, the first dielectric layer ILD1 covers the gate insulation layer GI and the gate G, and the second dielectric layer ILD2 covers the first dielectric layer ILD1.

In this embodiment, the first electrode E1 and the second electrode E2 are coupled with the channel A by the via (not shown) through the gate insulation layer GI, the first dielectric layer ILD1 and the second dielectric layer ILD2. In other embodiments, one end of the first electrode E1 and the second electrode E2 can be coupled with the channel A through the opening of an etch stop layer, and this disclosure is not limited.

The planarization layer PLN covers the second dielectric layer ILD2. The first end electrode 121 is disposed on the planarization layer PLN, and electrically coupled to the second electrode E2 through a via (not shown) of the planarization layer PLN. The pixel defining layer PDL is disposed on the first end electrode 121 and filled in the via of the planarization layer PLN. The light-emitting layer 123 and the second end electrode 122 are disposed on the first end electrode 121 in order, and the second end electrode 122 covers the pixel defining layer PDL. In this embodiment, the first end electrode 121 is, for example, the anode of the light-emitting element 12, and the second end electrode 122 is, for example, the cathode of the light-emitting element 12. In other embodiments, the first end electrode 121 can be the cathode of the light-emitting element 12, and the second end electrode 122 can be the anode of the light-emitting element 12. This disclosure is not limited.

The first end electrode 121 and the second end electrode 122 can be made of transparent conductive material, metal material, alloy material or combinations thereof. The transparent conductive material can be, for example but not limited to, ITO, IZO, AZO, CTO, SnO₂, or ZnO. In addition, the touch display device 1 may emit light upwardly or downwardly. The anode of the light-emitting element 12 can be an ITO/Ag/ITO structure, and the cathode thereof can be magnesium alloy.

The cover layer 13 is disposed opposite to the TFT substrate 11, and the light-emitting element 12 is disposed between the cover layer 13 and the TFT substrate 11. The cover layer 13 can be a rigid plate (e.g. glass), a flexible plate (e.g. flexible substrate) or other suitable film. In addition, the encapsulation layer FL is disposed between the cover layer 13 and the second end electrode 122. The encapsulation layer FL is filled with gas or comprises an organic material, an inorganic material, an adhesive material or combination thereof. The gas comprises air, inert gas or drying agent. The adhesive layer comprises an optical clear adhesive (OCA) or an optical clear resin (OCR). In one embodiment, the encapsulation layer is a combination of at least one organic layer and at least one inorganic layer for blocking water and oxygen. For example, the encapsulation layer can be a combination of inorganic layer/organic layer/inorganic layer. In one embodiment, the encapsulation layer can be a compressible layer, any of the above examples that has a compressible property is suitable.

When the scan lines SL of the touch display device 1 receive the scan signals to turn on the transistors T1, the corresponding data lines DL receive the data signals to charge the storage capacitors CS. Afterwards, the storage voltage of the storage capacitor CS can control to turn on the driving transistor T2, so that the first power source VDD (e.g. +5V) and the second power source VSS (e.g. 0V) apply the positive bias to the light-emitting element 12 of the pixel structure to enable the light-emitting element 12 to emit light. Accordingly, the touch display device 1 can display the image. Alternatively, the source of the driving transistor T2 can be coupled to a switch transistor (not shown) in series for controlling the lighting of the light-emitting element 12.

The transmission electrode TX and the sensing electrode RX are respectively disposed on the light-emitting layer 123. In this embodiment, the 2D touch function (XY plane) can be achieved by mutual capacitance touch control. The sensing electrode RX is a horizontal sensing electrode, and the variations of the capacitance between the sensing electrode RX and the transmission electrode TX can be detected for sensing the touch event in two directions (including a first direction X and a second direction Y, the XY plane).

FIG. 1A is a sectional view showing a part of the touch display device according to an embodiment of the disclosure, and FIG. 1C is a top view of the transmission electrode TX and the sensing electrode RX according to an aspect of the disclosure. FIG. 1A is a sectional view along the line B-B of FIG. 1C. The transmission electrode TX and the sensing electrode RX are disposed on the light-emitting layer 123. The transmission electrode TX is disposed at the outer side 131 of the cover layer 13, and the sensing electrode RX is disposed at the inner side 132 of the cover layer 13. In another embodiment (not shown), the transmission electrode TX is disposed at the inner side 132 of the cover layer 13, and the sensing electrode RX is disposed at the outer side 131 of the cover layer 13. In still another embodiment (not shown), the transmission electrode TX and the sensing electrode RX are disposed at the inner side 132 of the cover layer 13. In still another embodiment (not shown), the transmission electrode TX and the sensing electrode RX are disposed at the outer side 131 of the cover layer 13. To be noted, the outer side 131 is one side of the cover layer 13 away from the TFT substrate 11, and the inner side 132 is one side of the cover layer 13 close to the TFT substrate 11.

In the touch display device 1, the TFT substrate 11 and the cover layer 13 together form a touch panel 100. For example, a sealant (not shown) is provided to bond the TFT substrate 11 and the cover layer 13, and to seal the encapsulation layer FL therein. The sealant is, for example, a UV gel, frit, or the likes. In other words, the transmission electrode TX and the sensing electrode RX are integrated in the structure of the touch panel 100. As mentioned above, the touch display device 1 is an in-cell touch display device, and the touch panel 100 itself has a touch control function. Accordingly, the additional touch panel disposed at the outer side of the cover layer 13 is unnecessary. In addition, the circuit for controlling the touch function and the circuit for controlling the display function can be integrated in the same control IC, so that the processes for manufacturing the touch panel and the cost of the control IC can be reduced.

In some embodiment, the second end electrode 122 can be functioned as the touch electrode. Alternatively, at least one of the transmission electrode and the sensing electrode is the same structure of the second end electrode 122. Some related examples will be described herein below. To be noted, some components of the touch display device of the following examples are the same as or similar to those of the above-mentioned touch display device 1 of FIG. 1A, so the detailed descriptions thereof will be omitted.

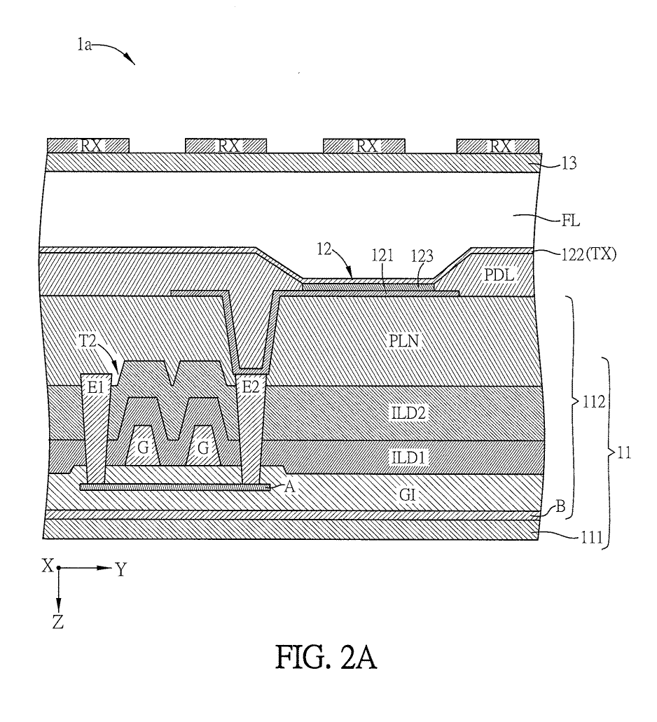

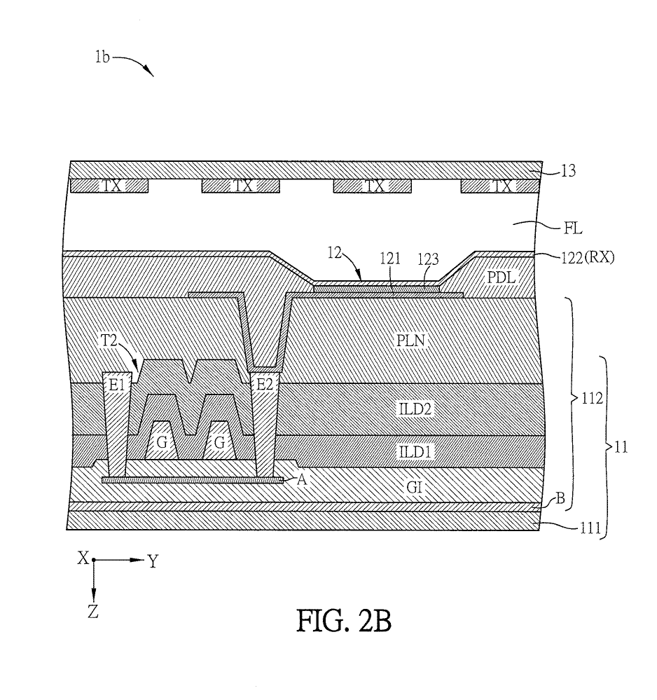

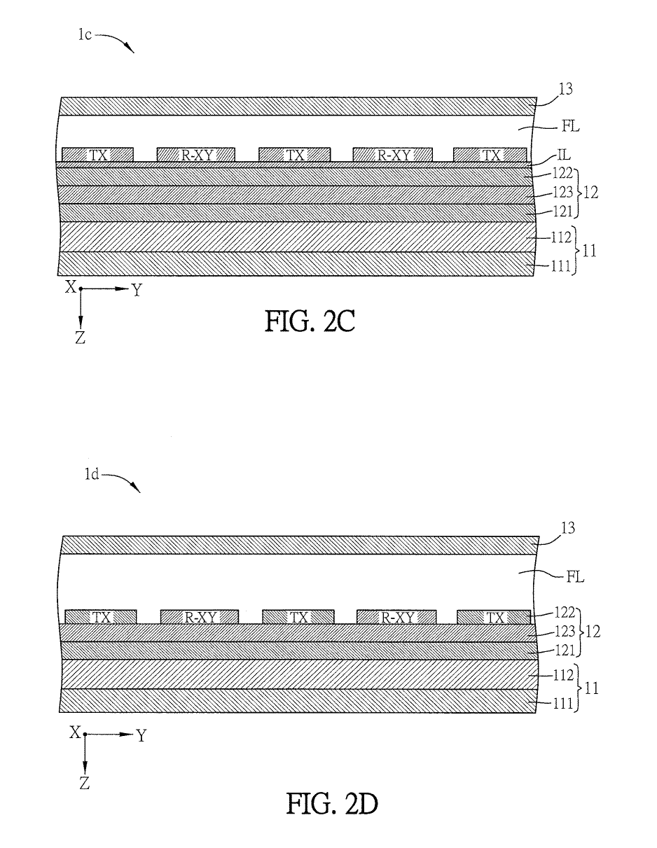

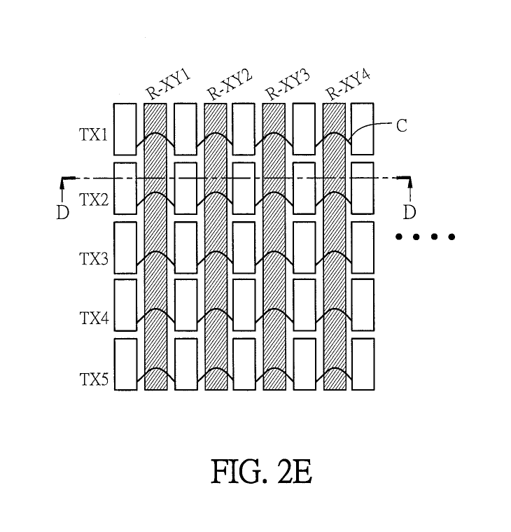

Different from the touch display device 1 of FIG. 1A, in the touch display device 1a of FIG. 2A, the sensing electrode RX is disposed at the outer side of the cover layer 13, and the transmission electrode TX and the second end electrode 122 are integrated as one component (the transmission electrode TX and the second end electrode 122 are the same component). In this case, the second end electrode 122 is the cathode of the light-emitting element 12. In other words, as shown in FIG. 2A, the second end electrode 122 of the light-emitting element 12 is also functioned as the transmission electrode TX of the touch display device 1a. Herein, the second end electrode 122 can be formed as any desired pattern, and this disclosure is not limited. In some embodiments (e.g. in the part-time driving mode), the second end electrode 122 is functioned as the cathode during the display period, and is functioned as the transmission electrode TX during the touch control period. In other embodiments, the sensing electrode RX can be disposed at the inner side of the cover layer 13, and the transmission electrode TX and the second end electrode 122 are integrated as one component. This disclosure is not limited.

Different from the touch display device 1a of FIG. 2A, in the touch display device 1b of FIG. 2B, the transmission electrode TX is disposed at the inner side of the cover layer 13, and the sensing electrode RX and the second end electrode 122 are integrated as one component. In other words, the second end electrode 122 of the light-emitting element 12 is also functioned as the sensing electrode RX of the touch display device 1b. Herein, the second end electrode 122 can be formed as any desired pattern, and this disclosure is not limited. In some embodiments (e.g. in the part-time driving mode), the second end electrode 122 is functioned as the cathode during the display period, and is functioned as the sensing electrode RX during the touch control period. In other embodiments, the transmission electrode TX can be disposed at the outer side of the cover layer 13, and the sensing electrode RX and the second end electrode 122 are integrated as one component. This disclosure is not limited.

In some embodiments of the disclosure, at least one of the transmission electrode and the sensing electrode is disposed between the second end electrode 122 and the encapsulation layer FL. Some examples will be described herein below.

FIG. 2C is a sectional view of the touch display device 1c according to another embodiment of the disclosure. To be noted, some components of the touch display device 1c are the same as or similar to those of the above-mentioned the touch display device 1 of FIG. 1A, so the detailed descriptions thereof will be omitted. FIG. 2C mainly shows the positions of the transmission electrode and the sensing electrode. FIG. 2E is a top view showing the arrangement of the transmission electrode TX and the sensing electrode RX. Two adjacent transmission electrodes TX are connected by a wire C, which crosses one horizontal sensing electrode R-XY. FIG. 2C is a sectional view along the line D-D of FIG. 2E.

Different from the structure of FIG. 1A, the transmission electrode TX and the horizontal sensing electrode R-XY are disposed at the same layer (as shown in FIG. 2C). The transmission electrode TX is disposed on the second end electrode 122, and an insulation layer IL is disposed between the transmission electrode TX and the second end electrode 122. The transmission electrodes TX and the horizontal sensing electrodes R-XY can be alternately disposed, and they can be formed by patterning one conductive layer. In this case, the horizontal sensing electrode R-XY can sensing the touch event in the XY plane (2D touch). In some embodiments, one of the transmission electrode TX and the horizontal sensing electrode R-XY is disposed at the inner side or the outer side of the cover layer 13, and the other one is disposed between the second end electrode 122 and the encapsulation layer FL. This disclosure is not limited.

FIG. 2D is a sectional view of the touch display device 1d according to another embodiment of the disclosure. The transmission electrode TX and the horizontal sensing electrode R-XY are integrated with the second end electrode 122 to form one component. In this embodiment, the second end electrode 122 is a patterned structure and configured as the transmission electrode TX or the horizontal sensing electrode R-XY. The transmission electrodes TX or the horizontal sensing electrodes R-XY are alternately disposed. One transmission electrode TX or one horizontal sensing electrode R-XY is corresponding to one or more pixel structures, and this disclosure is not limited.

In some embodiments, the sensing electrode of the touch display device can sense the 3D touch control signals, so that the touch display device can be applied to 3D touch control application. In addition, the encapsulation layer FL can be a compressible layer. When the touch display device is pressed, the encapsulation layer FL can have deformation so that the capacitance between the pressure sensing electrode (the vertical sensing electrode or 3D sensing electrode) and another electrode disposed at two sides of the encapsulation layer FL can be changed. As mentioned above, the encapsulation layer FL can be air, inert gas, an organic layer, an inorganic layer, an adhesive layer or combination thereof.

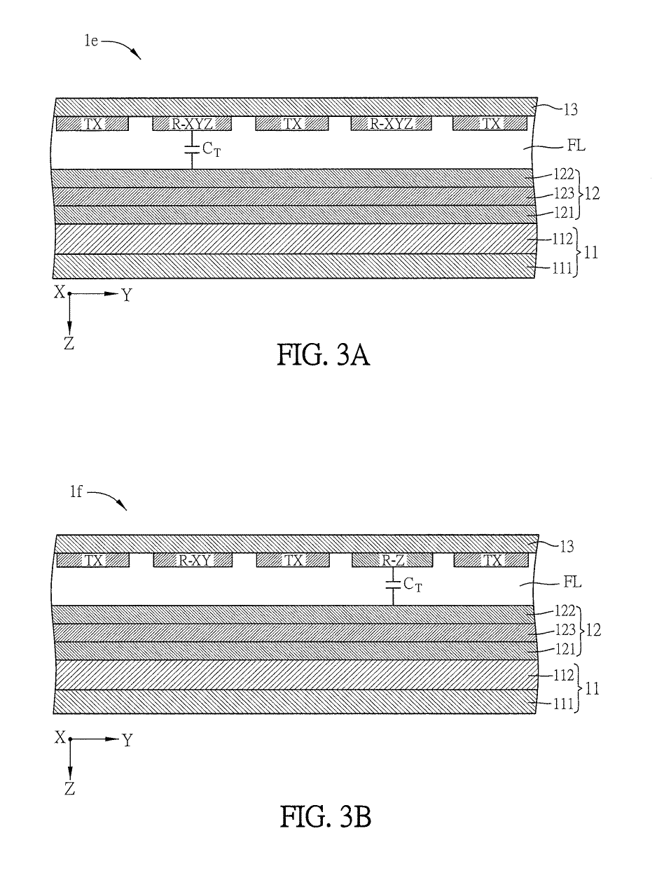

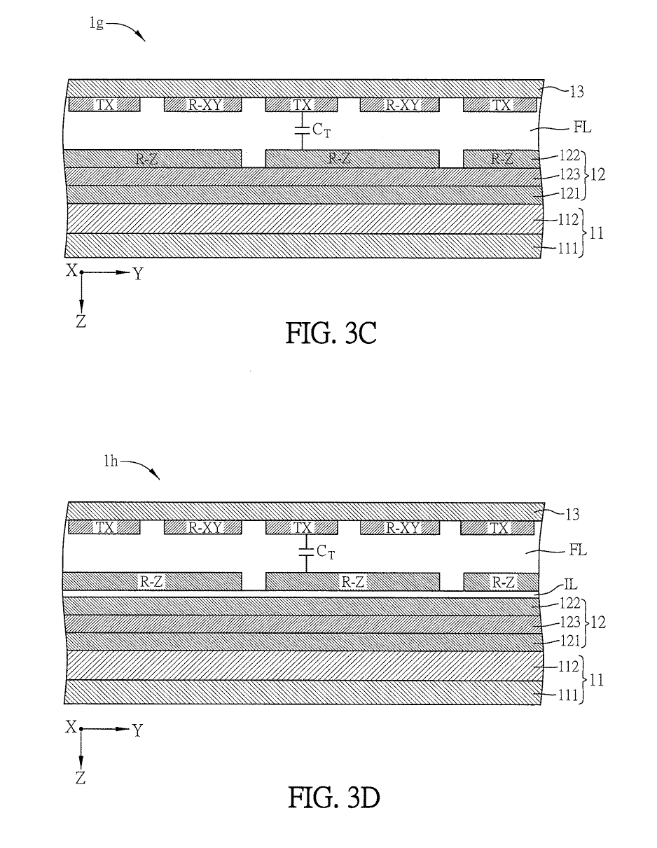

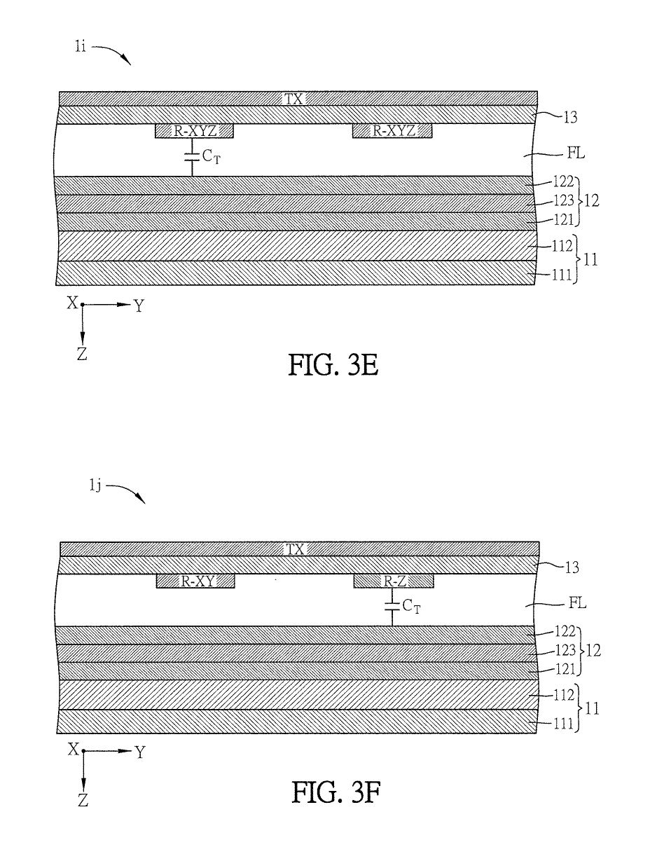

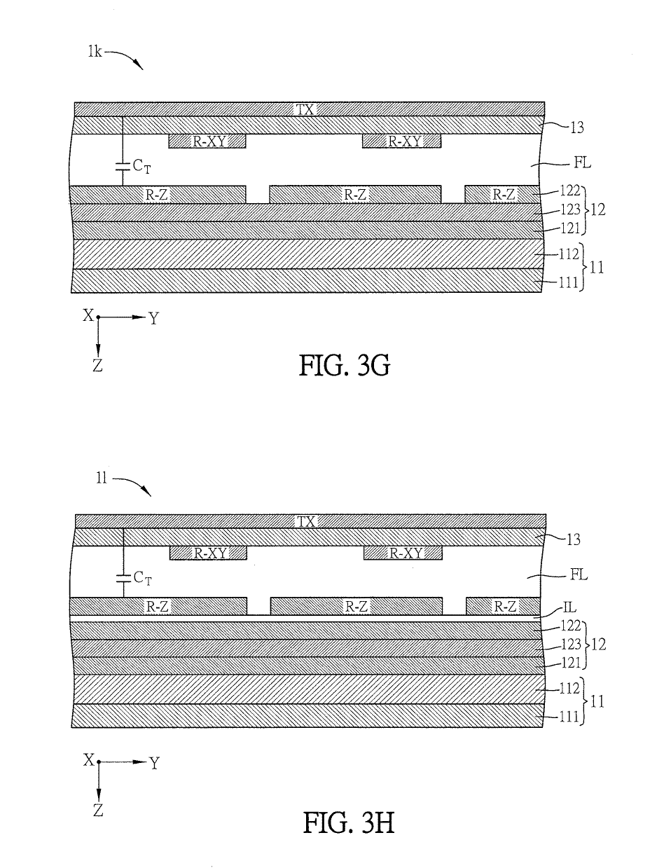

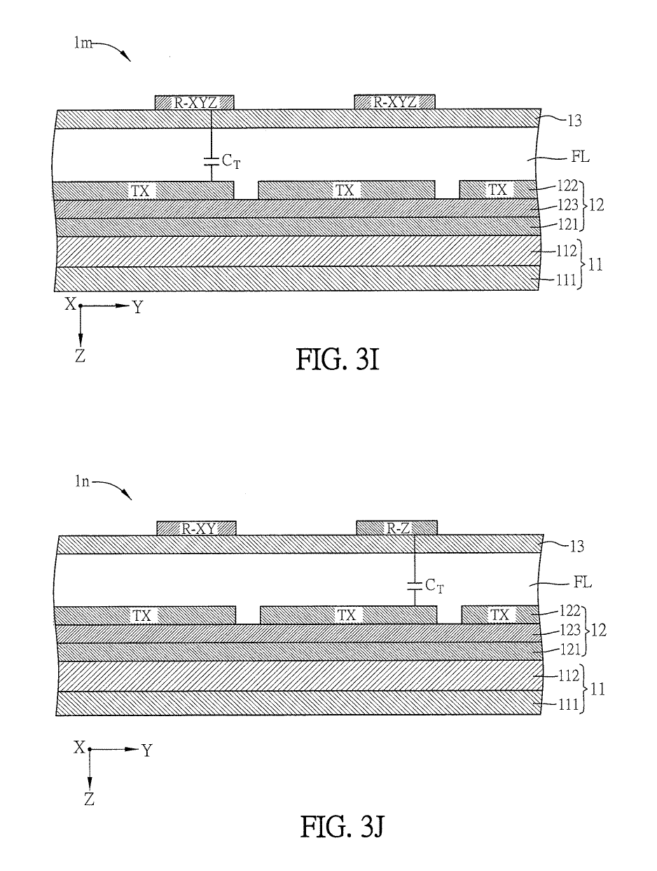

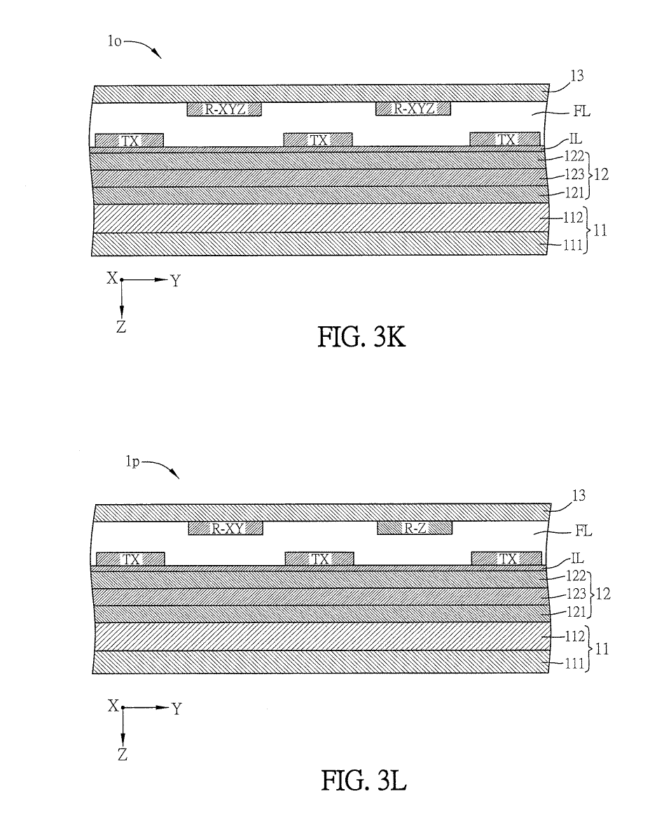

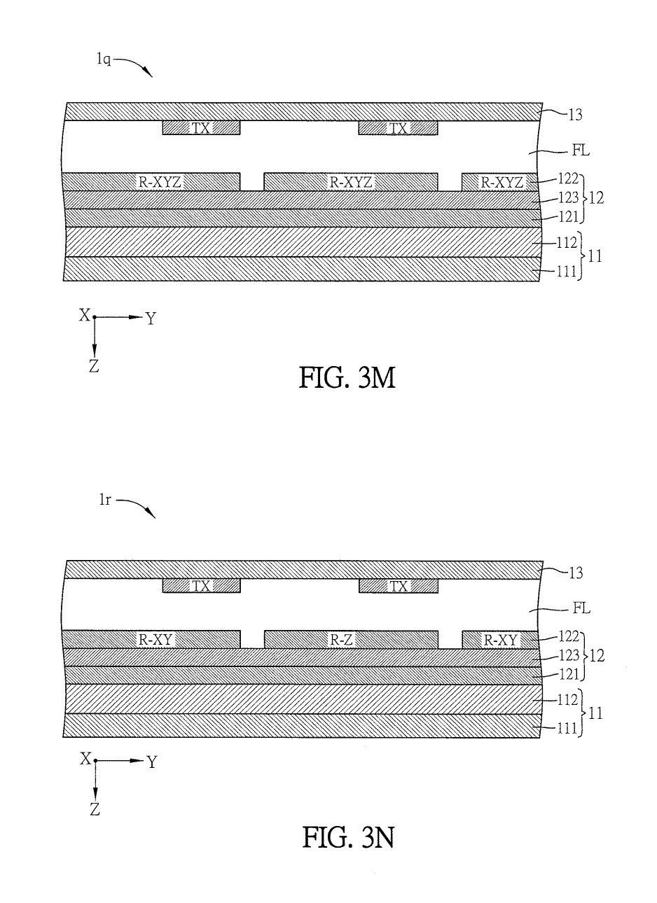

FIGS. 3A to 3N are schematic diagrams showing touch display devices 1e˜1r according to different embodiments of the disclosure. The sensing electrode may include a horizontal sensing electrode R-XY and a vertical sensing electrode R-Z or include a 3D sensing electrode R-XYZ. In this embodiment, the horizontal sensing electrode R-XY is used to sense the 2D touch event, and the vertical sensing electrode R-Z is used to sense the touch event in the third direction Z. Alternatively, the 3D sensing electrode R-XYZ is used to sense the 2D touch event and the 3D touch event. As mentioned above, the touch display devices 1e˜1r can sense the 2D touch event (the first direction X and the second direction Y) and the touch event in the third direction Z, thereby providing a good accuracy and preciseness in touch control.

In some embodiment, the sensing electrode is a 3D sensing electrode R-XYZ. At least one of the transmission electrode TX and the 3D sensing electrode R-XYZ is disposed at the inner side or the outer side of the cover layer 13. For example, the transmission electrode TX and the 3D sensing electrode R-XYZ can be both disposed at the inner side or the outer side of the cover layer 13, or they can be disposed at two sides of the cover layer 13, respectively. Some examples will be described hereinafter with reference to FIGS. 3A and 3E.

As shown in FIG. 3A, the sensing electrode of the touch display device 1e is a 3D sensing electrode R-XYZ. The transmission electrodes TX and the 3D sensing electrodes R-XYZ are alternately disposed at the inner side of the cover layer 13. The 2D and 3D touch event can be sensed by the variation of the mutual capacitance C_{T} between the 3D sensing electrodes R-XYZ and the second end electrode 122. In this embodiment, the encapsulation layer FL is a compressible layer. When the touch display device is pressed, the encapsulation layer FL can have deformation so that the mutual capacitance between the 3D sensing electrode R-XYZ and the second end electrode 122 can be changed.

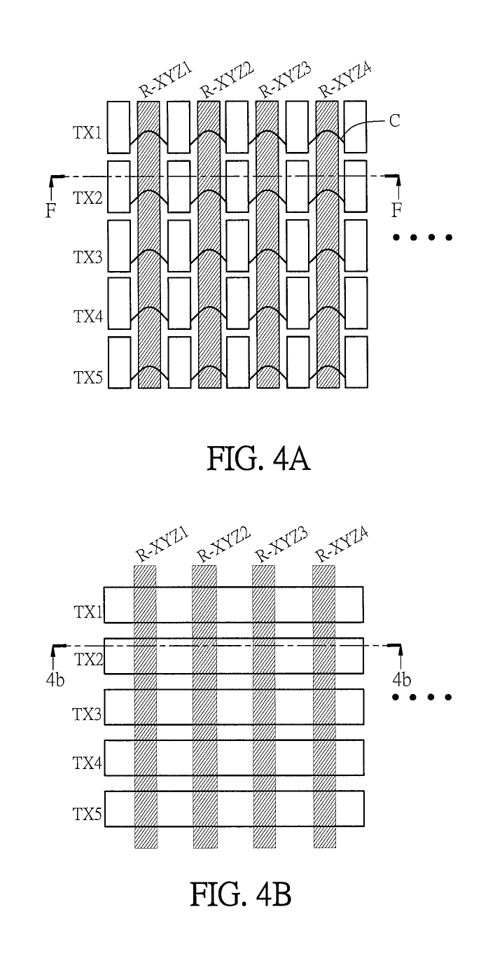

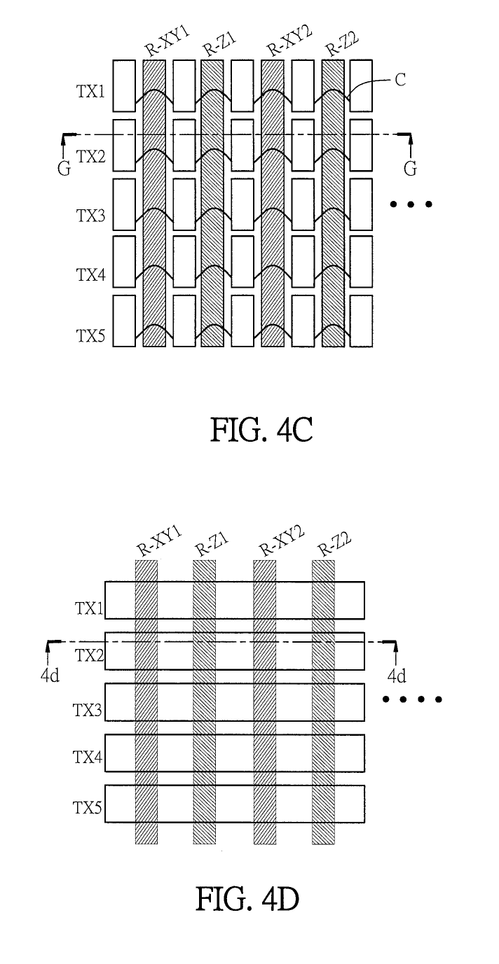

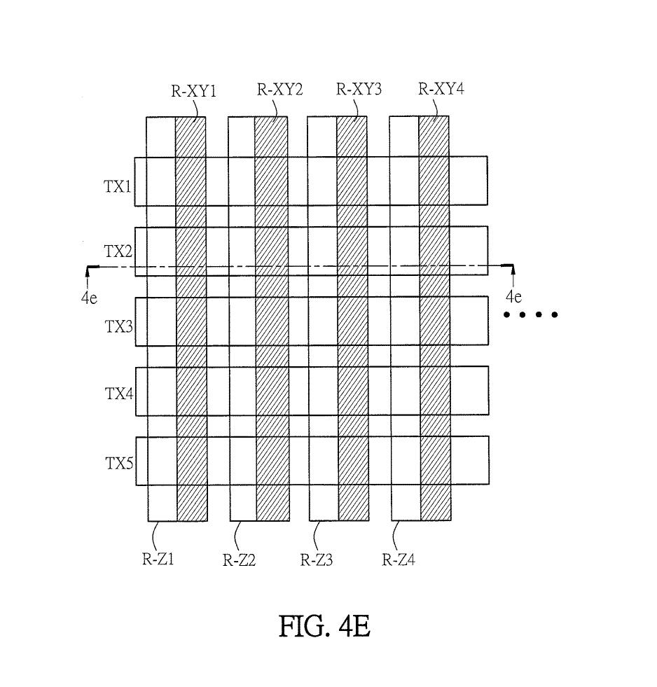

FIG. 4A is a top view of FIG. 3A, and FIG. 3A is a sectional view along the line F-F of FIG. 4A. The transmission electrode TX is a patterned structure, and the transmission electrodes TX and the 3D sensing electrodes R-XYZ are alternately disposed. Two adjacent transmission electrodes TX are connected by a wire C, which crosses one 3D sensing electrode R-XYZ. In another embodiment, the transmission electrode TX and the 3D sensing electrodes R-XYZ are both disposed at the outer side of the cover layer 13. In another embodiment, as shown in FIG. 3E, one of the transmission electrode TX and the 3D sensing electrodes R-XYZ is disposed at the inner side of the cover layer 13, and the other one is disposed at the outer side of the cover layer 13.

FIG. 4B is a top view of FIG. 3E, and FIG. 3E is a sectional view along the line 4b-4b of FIG. 4B. In this embodiment, the transmission electrodes TX are driven by a scan method, and two-stage touch control voltage thresholds are used for determining the touch event is a 2D touch event or a 3D touch event. In more detailed, a pulse signal is transmitted to the transmission electrodes TX in order, and the output voltage value is obtained according to the change of the capacitance C_{T} between the 3D sensing electrodes R-XYZ and the second end electrode 122 for determining the touch event is a 2D touch event or a 3D touch event. For example, when the obtained output voltage value is greater than or less than the threshold of a horizontal touch event, this touch event is determined as a 2D touch event. When the obtained output voltage value is greater than the threshold of a vertical touch event, this touch event is determined as a 3D touch event. Accordingly, the touch display device can generate a 2D touch control operation or a 3D touch control operation based on the above determining result.

In some embodiment, the sensing electrode includes a horizontal sensing electrode R-XY and a vertical sensing electrode R-Z. At least one of the transmission electrode TX, the horizontal sensing electrode R-XY and the vertical sensing electrode R-Z is disposed at the inner side or the outer side of the cover layer 13. For example, the transmission electrode TX, the horizontal sensing electrode R-XY and the vertical sensing electrode R-Z can be both disposed at the inner side or the outer side of the cover layer 13. Alternatively, one of the transmission electrode TX, the horizontal sensing electrode R-XY and the vertical sensing electrode R-Z is disposed at the outer sides of the cover layer 13, and the other two of the transmission electrode TX, the horizontal sensing electrode R-XY and the vertical sensing electrode R-Z are disposed at the inner sides of the cover layer 13. Or, one of the transmission electrode TX, the horizontal sensing electrode R-XY and the vertical sensing electrode R-Z is disposed at the inner sides of the cover layer 13, and the other two of the transmission electrode TX, the horizontal sensing electrode R-XY and the vertical sensing electrode R-Z are disposed at the outer sides of the cover layer 13. This disclosure is not limited. Some examples will be described hereinafter with reference to FIGS. 3B and 3F.

FIG. 3B is a schematic diagram showing a touch display device if according to another embodiment of the disclosure. Different from the device 1e of FIG. 3A, in the touch display device if of FIG. 3B, the sensing electrode includes a horizontal sensing electrode R-XY and a vertical sensing electrode R-Z. In the horizontal direction (the X-Y plane), the horizontal sensing electrode R-XY and the vertical sensing electrode R-Z are disposed between two transmission electrodes TX, respectively. In this embodiment, the horizontal sensing electrode R-XY, the vertical sensing electrode R-Z, and the transmission electrode TX are disposed at the inner side of the cover layer 13. FIG. 4C is a top view of FIG. 3B, and FIG. 3B is a sectional view along the line G-G of FIG. 4C. As shown in FIG. 4C, the transmission electrode TX is a patterned structure, and the transmission electrodes TX, the horizontal sensing electrode R-XY and the vertical sensing electrode R-Z are alternately disposed. Two adjacent transmission electrodes TX are connected by a wire C, which crosses one horizontal sensing electrode R-XY or one vertical sensing electrode R-Z. In this embodiment, the 2D touch event is sensed by the horizontal sensing electrode R-XY, and the touch event in the third direction Z is sensed by the variation of the mutual capacitance C_{T} between the vertical sensing electrode R-Z and the second end electrode 122.

In another embodiment, the transmission electrode TX and the horizontal sensing electrode R-XY are disposed at the outer side of the cover layer 13. In another embodiment, as shown in FIG. 3F, one of the transmission electrode TX and the horizontal sensing electrode R-XY is disposed at the inner side of the cover layer 13, and the other one is disposed at the outer side of the cover layer 13. FIG. 3F is a sectional view along the line 4d-4d of FIG. 4D. As shown in FIG. 4D, the transmission electrodes TX are separately disposed along one direction, and the horizontal sensing electrodes R-XY and the vertical sensing electrodes R-Z are separately disposed along another direction. The transmission electrodes TX are alternately disposed with the horizontal sensing electrodes R-XY and the vertical sensing electrodes R-Z.

In some embodiments, at least one of the transmission electrode TX, the horizontal sensing electrode R-XY and the vertical sensing electrode R-Z is functioned as the second end electrode. Some examples will be described hereinafter with reference to FIGS. 3C, 3G, 3J and 3N.

FIG. 3C is a sectional view of the touch display device 1g according to another embodiment of the disclosure. As shown in FIG. 3C, the sensing electrode includes a horizontal sensing electrode R-XY and a vertical sensing electrode R-Z. In this embodiment, the transmission electrode TX and the horizontal sensing electrode R-XY are alternately disposed at the inner side of the cover layer 13. The second end electrode 122 is a patterned structure, and the vertical sensing electrode R-Z and the second end electrode 122 are integrated as one component. In some embodiments (e.g. the part-time driving mode), the second end electrode 122 is functioned as the cathode during the display period, and is functioned as the vertical sensing electrode R-Z during the touch control period. In this case, the touch event in the third direction Z is sensed by the variation of the mutual capacitance between the transmission electrode TX and the second end electrode 122 (the vertical sensing electrode R-Z).

In some embodiments, one of the transmission electrode TX and the vertical sensing electrode R-Z is disposed at the inner side or the outer side of the cover layer 13, and the other one is commonly used as the second end electrode 122. The horizontal sensing electrode R-XY can be disposed at the inner side or the outer side of the cover layer 13, or be commonly used as the second end electrode 122. As shown in FIG. 3G, the transmission electrode TX and the sensing electrode R-XY are disposed at the outer side and the inner side of the cover layer 13, respectively, and the vertical sensing electrode R-Z is commonly used as the second end electrode 122. FIG. 4E is a top view of FIG. 3G and FIG. 3G is a sectional view along the line 4e-4e of FIG. 4E. As shown in FIG. 4E, the transmission electrodes TX are separately disposed along one direction, and the horizontal sensing electrodes R-XY and the vertical sensing electrodes R-Z are separately disposed along another direction and are partially overlapped in the vertical direction (direction Z). In addition, the transmission electrodes TX are alternately disposed with the horizontal sensing electrodes R-XY and the vertical sensing electrodes R-Z.

As shown in FIG. 3J, the vertical sensing electrode R-Z and the horizontal sensing electrode R-XY are disposed at the outer side of the cover layer 13, and the transmission electrode TX is commonly used as the second end electrode 122. As shown in FIG. 3N, the transmission electrode TX is disposed at the inner side of the cover layer 13, and the vertical sensing electrode R-Z and the horizontal sensing electrode R-XY are commonly used as the second end electrode 122. In this case, the vertical sensing electrode R-Z and the horizontal sensing electrode R-XY are separately disposed, and integrated with the second end electrode 122 as one component.

In some embodiments, the sensing electrode is a 3D sensing electrode R-XYZ. One of the transmission electrode TX and the 3D sensing electrode R-XYZ is commonly used as the second end electrode 122 (they are the same component). For example, one of the transmission electrode TX and the 3D sensing electrode R-XYZ is disposed at the inner side or the outer side of the cover layer 13, and the other one is commonly used as the second end electrode 122 (the same component). As shown in FIG. 3I, the 3D sensing electrode R-XYZ is disposed at the outer side of the cover layer 13, and the transmission electrode TX is commonly used as the second end electrode 122. In this case, the transmission electrode TX and the patterned second end electrode 122 are integrated as one component. As shown in FIG. 3M, the transmission electrode TX is disposed at the inner side of the cover layer 13, and the 3D sensing electrode R-XYZ is commonly used as the second end electrode 122. In this case, the 3D sensing electrode R-XYZ and the patterned second end electrode 122 are integrated as one component.

In some embodiments, at least one of the transmission electrode TX, the horizontal sensing electrode R-XY and the vertical sensing electrode R-Z is disposed between the second end electrode 122 and the encapsulation layer FL. In some embodiments, one of the transmission electrode TX and the vertical sensing electrode R-Z is disposed at the inner side or the outer side of the cover layer 13, and the other one is disposed on the second end electrode 122 with an insulation layer IL disposed therebetween. This disclosure is not limited. Some examples will be described hereinafter with reference to FIGS. 3D, 3H and 3L.

FIG. 3D is a sectional view of the touch display device 1h according to another embodiment of the disclosure. As shown in FIG. 3D, the vertical sensing electrode R-Z is disposed on the second end electrode 122 and located between the second end electrode 122 and the encapsulation layer FL. In addition, an insulation layer IL is disposed between the vertical sensing electrode R-Z and the second end electrode 122. The transmission electrode TX and the horizontal sensing electrode R-XY are both disposed at the inner side of the cover layer 13. As shown in FIG. 3H, the transmission electrode TX is disposed at the outer side of the cover layer 13, and the horizontal sensing electrode R-XY is disposed at the inner side of the cover layer 13. The vertical sensing electrode R-Z is disposed on the second end electrode 122, and an insulation layer IL is disposed between the vertical sensing electrode R-Z and the second end electrode 122. As shown in FIG. 3L, the vertical sensing electrode R-Z and the horizontal sensing electrode R-XY are both disposed at the inner side of the cover layer 13. The transmission electrode TX is disposed on the second end electrode 122, and an insulation layer IL is disposed between the transmission electrode TX and the second end electrode 122.

In some embodiments, the sensing electrode is a 3D sensing electrode R-XYZ. One of the transmission electrode TX and the 3D sensing electrode R-XYZ is disposed between the second end electrode 122 and the encapsulation layer FL. For example, one of the transmission electrode TX and the 3D sensing electrode R-XYZ is disposed at the inner side or the outer side of the cover layer 13, and the other one is disposed between the second end electrode 122 and the encapsulation layer FL with an insulation layer IL disposed therebetween. As shown in FIG. 3K, the 3D sensing electrode R-XYZ is disposed at the inner side of the cover layer 13, and the transmission electrode TX is disposed on the second end electrode 122. An insulation layer IL is disposed between the transmission electrode TX and the second end electrode 122.

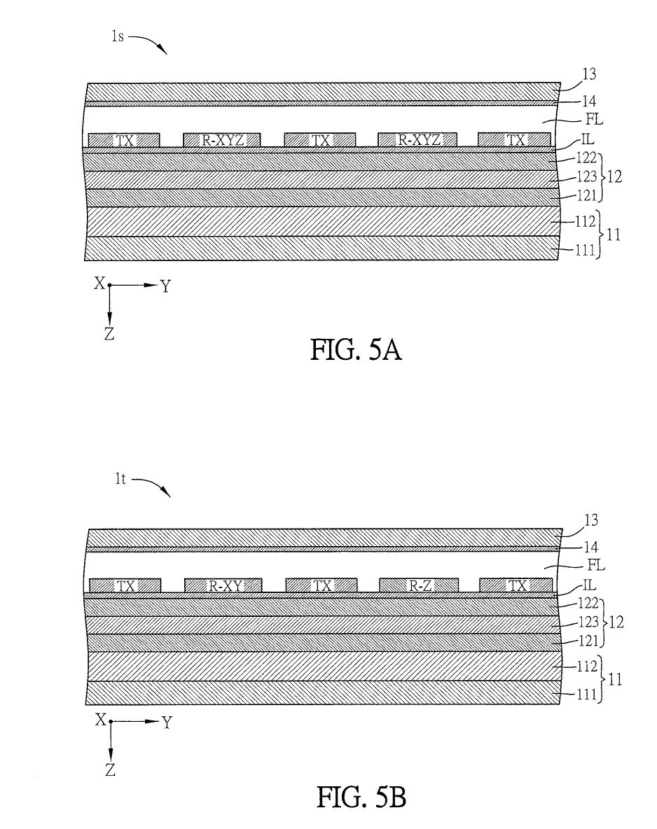

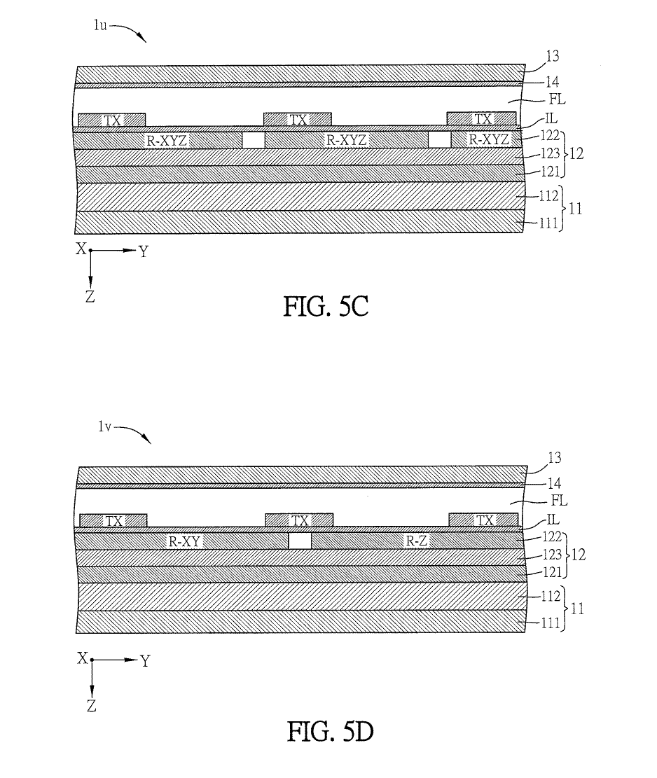

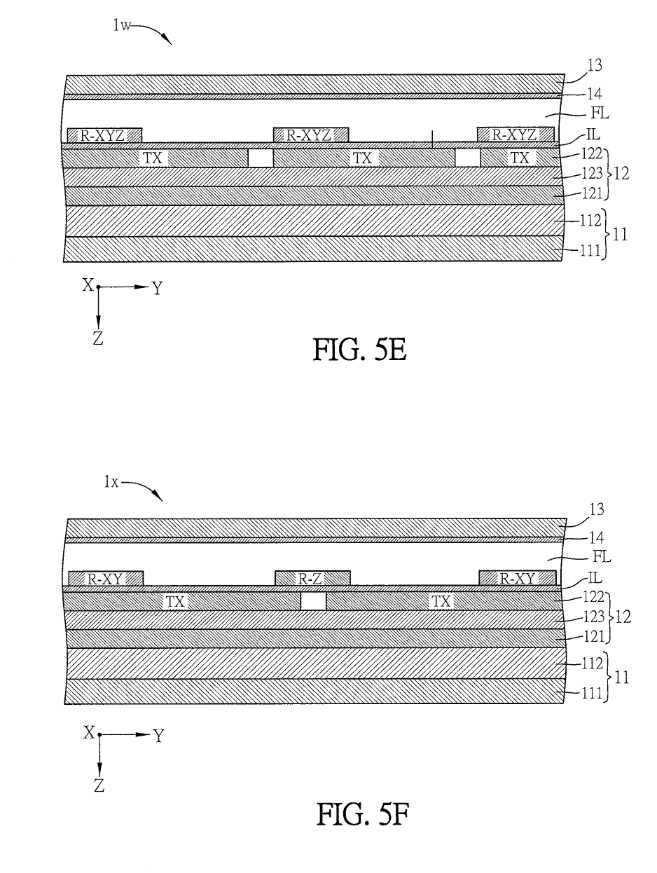

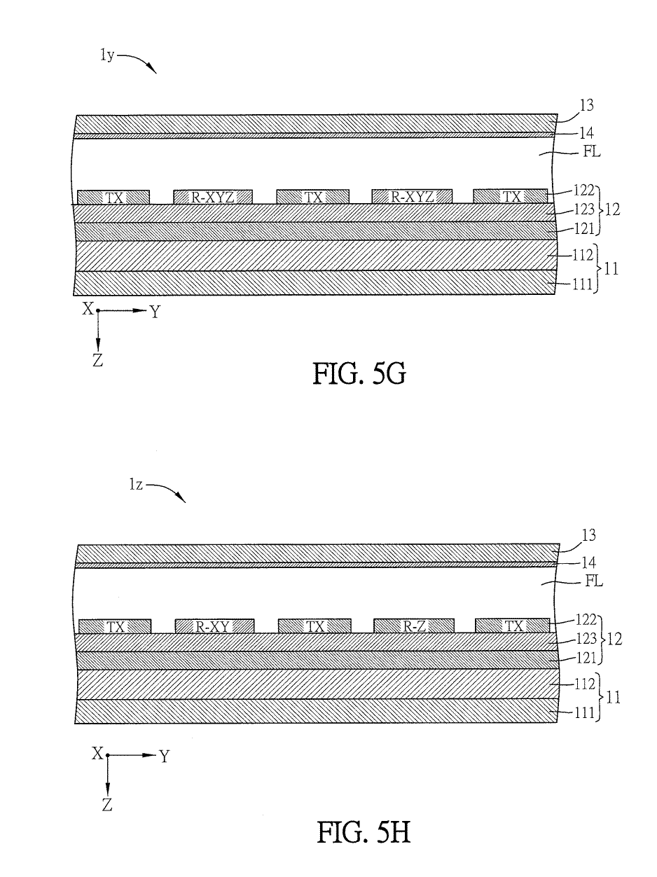

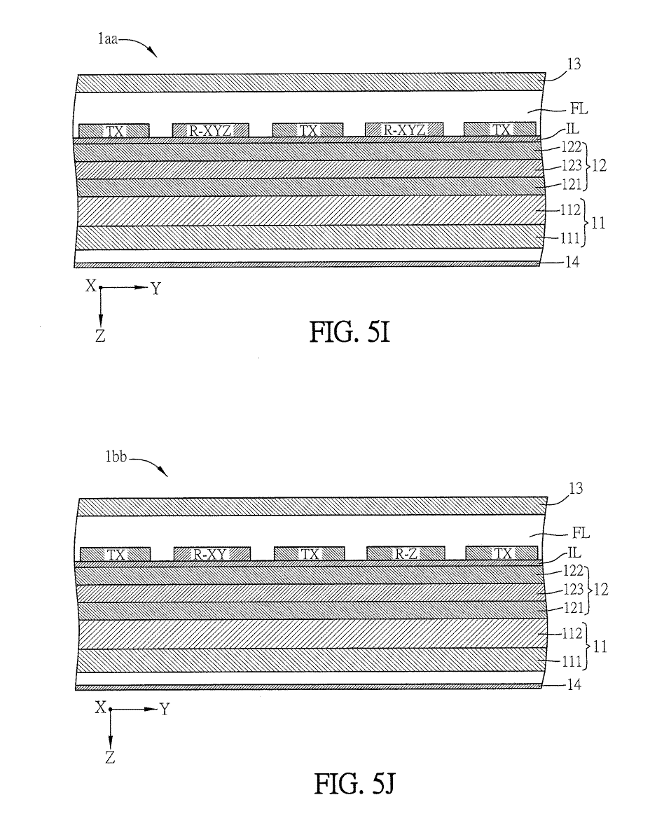

FIGS. 5A to 5J are schematic diagrams showing touch display devices 1s˜1bb, which further include a reference electrode, according to different embodiments of the disclosure. The touch display devices 1s˜1bb also have the 3D touch control function. FIGS. 5A, 5G and 5I show the sectional structures of the driving electrodes and sensing electrodes along the line F-F of FIG. 4A, FIGS. 5B, 5H and 5J show the sectional structures of the driving electrodes and sensing electrodes along the line G-G of FIG. 4C. In other embodiments, the sectional structures of the driving electrodes and sensing electrodes can be corresponding to FIG. 4A, 4D or 4E, and this disclosure is not limited.

In some embodiments, the touch display device further includes a reference electrode, which is disposed at the inner side or the outer side of the cover layer 13 or at one side of the TFT substrate 11 away from the light-emitting element 12.

As shown in FIG. 5A, the touch display device is further includes a reference electrode 14, which is disposed at the inner side of the cover layer 13. The transmission electrodes TX and the 3D sensing electrodes R-XYZ are separately disposed on the second end electrode 122, with an insulation layer IL disposed therebetween. In this case, the 2D touch event and the 3D touch event are sensed by the variation of the mutual capacitance between the 3D sensing electrodes R-XYZ and the reference electrode 14. In some embodiments, the transmission electrodes TX and the 3D sensing electrodes R-XYZ are separately disposed at the outer side of the cover layer 13. Alternatively, the transmission electrodes TX are disposed at the outer side of the cover layer 13, and the 3D sensing electrodes R-XYZ are disposed on the second end electrode 122. Or, the 3D sensing electrodes R-XYZ are disposed at the outer side of the cover layer 13, and the transmission electrodes TX are disposed on the second end electrode 122. This disclosure is not limited.

Different from the touch display device 1s, the sensing electrode of the touch display device 1t of FIG. 5B includes a horizontal sensing electrode R-XY and a vertical sensing electrode R-Z, and the transmission electrodes TX, the horizontal sensing electrodes R-XY and the vertical sensing electrodes R-Z are arranged in order and separately disposed on the second end electrode 122. In this case, the 2D touch event is sensed by the variation of the mutual capacitance between the horizontal sensing electrodes R-XY and the reference electrode 14, and the touch event in the third direction Z is sensed by the variation of the mutual capacitance between the vertical sensing electrodes R-Z and the reference electrode 14. In other embodiments, the reference electrode 14 can be disposed at the outer side of the cover layer 13.

Different from the touch display device 1s, the 3D sensing electrode R-XYZ and the patterned second end electrode 122 of the touch display device 1u of FIG. 5C are integrated as one component. The transmission electrode TX is disposed on the second end electrode 122, and an insulation layer IL is disposed therebetween. In this case, the touch event in the third direction Z is sensed by the variation of the mutual capacitance between the reference electrode 14 and the patterned second end electrode 122 (the 3D sensing electrode R-XYZ). In other embodiments, the positions of the transmission electrode TX and the 3D sensing electrode R-XYZ can be switched as shown in FIG. 5E. Alternatively, the transmission electrode TX can be disposed at the outer side of the cover layer 13. Other arrangements can be considered, and this disclosure is not limited.

Different from the touch display device 1u, the touch display device 1v of FIG. 5D includes a horizontal sensing electrode R-XY and a vertical sensing electrode R-Z instead of the 3D sensing electrode R-XYZ. In this case, the horizontal sensing electrodes R-XY and the vertical sensing electrodes R-Z are separately and alternately disposed and are integrated with the second end electrode 122 as one component. In other embodiments, the positions of the transmission electrode TX, the horizontal sensing electrodes R-XY and the vertical sensing electrodes R-Z can be switched as shown in FIG. 5F. Alternatively, the transmission electrode TX can be disposed at the outer side of the cover layer 13. Other arrangements can be considered, and this disclosure is not limited.

Different from the touch display device 1s of FIG. 5A, the transmission electrode TX and the 3D sensing electrode R-XYZ of the touch display device 1y of FIG. 5G are respectively integrated with the second end electrode 122 as one component.

Different from the touch display device 1t of FIG. 5B, the transmission electrode TX, the horizontal sensing electrodes R-XY and the vertical sensing electrodes R-Z of the touch display device 1z of FIG. 5H are respectively integrated with the second end electrode 122 as one component.

Different from the touch display device 1s of FIG. 5A, the reference electrode 14 of the touch display device 1aa of FIG. 5I is disposed at one side of the TFT substrate 11 away from the light-emitting element 12.

Different from the touch display device 1t of FIG. 5B, the reference electrode 14 of the touch display device 1bb of FIG. 5J is disposed at one side of the TFT substrate 11 away from the light-emitting element 12.

In other embodiments, the reference electrode 14 of any of the touch display device 1s-1z of FIGS. 5C to 5H and their modifications can be disposed at one side of the TFT substrate 11 away from the light-emitting element 12, and this disclosure is not limited.

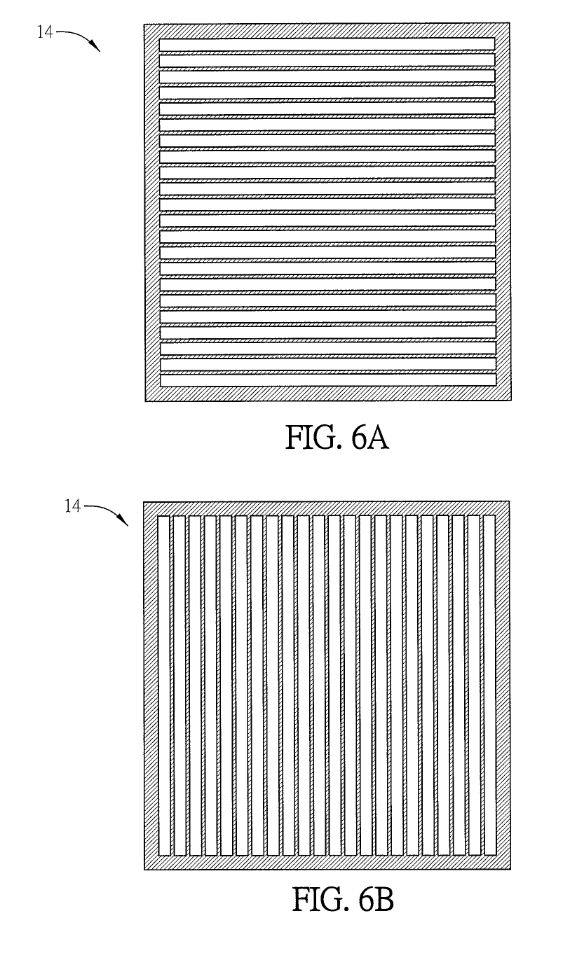

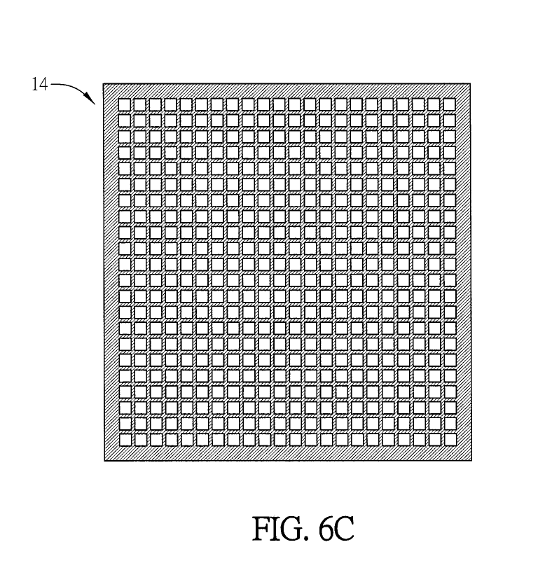

In some embodiments, the reference electrode 14 can be any of the patterned electrodes of FIGS. 6A to 6C (bar-type or grid-type), or it can be an entire plate of electrode. This disclosure is not limited. In addition, the reference electrode 14 can also be the metal frame or metal film originally used in the display device, which is made of transparent material (e.g. ITO) or opaque material (e.g. metal). This disclosure is not limited.

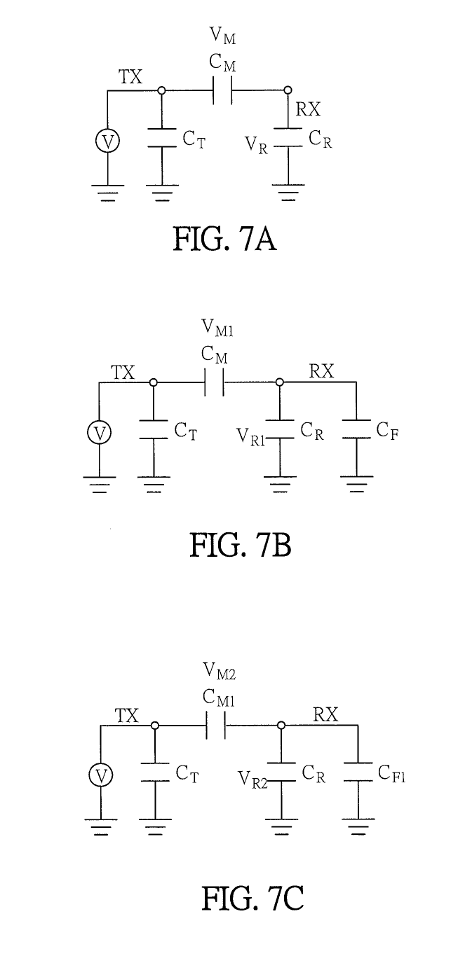

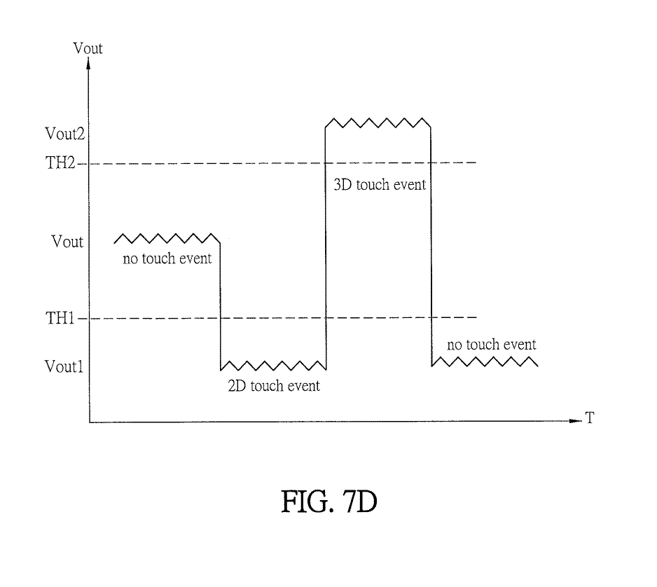

FIG. 7A is a schematic diagram of the control circuit of the touch display device of the disclosure when the 3D sensing electrode R-XYZ senses the 2D and 3D touch events in the situation of no touch event, FIG. 7B is a schematic diagram of the control circuit of the touch display device of the disclosure when the 3D sensing electrode R-XYZ senses the 2D and 3D touch events in the situation of having 2D touch event, and FIG. 7C is a schematic diagram of the control circuit of the touch display device of the disclosure when the 3D sensing electrode R-XYZ senses the 2D and 3D touch events in the situation of having 3D touch event. FIG. 7D is a schematic diagram showing the waveform of the touch signal Vout in the situations of no touch event, having 2D touch event, and having 3D touch event.

As shown in FIG. 7A, the touch signal Vout in the situation of no touch event can be obtained as follow:

$$V = {V}_{M} + {V}_{R}$$

$${V}_{R} = \frac{{C}_{M}}{{C}_{R} + {C}_{M}} \times V = xV$$

$${V}_{M} = \frac{{C}_{R}}{{C}_{R} + {C}_{M}} \times V = yV$$

$${V}_{out} = {V}_{R} \times n$$

As shown in FIG. 7B, the touch signal Vout in the situation of having 2D touch event can be obtained as follow:

$$V = {V}_{M} + {V}_{R}$$

$${V}_{R 1} = \frac{{C}_{M}}{{C}_{R} + {C}_{M} + {C}_{F}} \times V = {x}_{1} V$$

$${V}_{M 1} = \frac{{C}_{R} + {C}_{F}}{{C}_{R} + {C}_{M} + {C}_{F}} \times V = {y}_{1} V$$

$${V}_{out 1} = {V}_{R 1} \times n$$

As shown in FIG. 7C, the touch signal Vout in the situation of having 3D touch event can be obtained as follow:

$$V = {V}_{M} + {V}_{R}$$

$${V}_{R 2} = \frac{{C}_{M 1}}{{C}_{R} + {C}_{M 1} + {C}_{F 1}} \times V = {x}_{2} V$$

$${V}_{M 2} = \frac{{C}_{R} + {C}_{F 1}}{{C}_{R} + {C}_{M 1} + {C}_{F 1}} \times V = {y}_{2} V$$

$${V}_{out 2} = {V}_{R 2} \times n$$

Wherein, C_{M} is a mutual capacitance between two electrodes, C_{T} is the capacitance of the transmission electrode TX, C_{R} is the capacitance of the 3D sensing electrode R-XYZ, C_{F} is, for example, a capacitance generated by the contact of the finger, and n is an internal magnification of the IC.

FIG. 10 is a schematic block diagram showing the touch detecting circuit 15 and the sensing electrode RX of the touch display device according to an embodiment of the disclosure. Referring to FIG. 10, the touch display device further includes a touch detecting circuit 15, which is electrically connected with the sensing electrode RX. The touch detecting circuit 15 can provide a horizontal touch voltage threshold value TH1 and a vertical touch voltage threshold value TH2.

When the touch display device is touched or pressed, the horizontal touch voltage threshold value, which is the detecting threshold for the touch event in the horizontal direction (2D), is different from the vertical touch voltage threshold value, which is the detecting threshold for the touch event in the vertical direction (3D). In this case, two-stage touch voltage threshold values are provided to distinguish the touch event is a 2D touch event or a 3D touch event. In this embodiment, as shown in FIG. 7D, the touch signal voltage threshold value for a 2D touch event (the horizontal touch voltage threshold value) is TH1, and the touch signal voltage threshold value for a 3D touch event (the vertical touch voltage threshold value) is TH2. The value TH1 is different from the value TH2. When the touch detecting circuit 15 detects the touch signal and determines that, for example, the voltage Vout1 is lower than the voltage threshold value TH1, the touch event is detected as a 2D touch event. When the touch detecting circuit 15 detects the touch signal and determines that, for example, the voltage Vout2 is greater than the voltage threshold value TH2, the touch event is detected as a 3D touch event. By detecting the voltage value of the touch signal Vout, the control circuit can distinguish whether the touch event is a 2D touch event or a 3D touch event and then generate the corresponding control operation. Compared with the situation of no touch event, the signal in the situation of having touch event is changed (become larger or smaller), and this disclosure is not limited. For example as shown in FIG. 7D, compared with the situation of no touch event, the voltage in the situation of having 2D touch event becomes smaller, and the voltage in the situation of having 3D touch event becomes larger. This disclosure is not limited. In another embodiment, compared with the situation of no touch event, the voltage in the situation of having 2D touch event becomes larger, and the voltage in the situation of having 3D touch event becomes smaller. In another embodiment, compared with the situation of no touch event, the voltage in the situation of having 2D touch event becomes larger, and the voltage in the situation of having 3D touch event also becomes larger. In another embodiment, compared with the situation of no touch event, the voltage in the situation of having 2D touch event becomes smaller, and the voltage in the situation of having 3D touch event also becomes smaller. This disclosure is not limited.

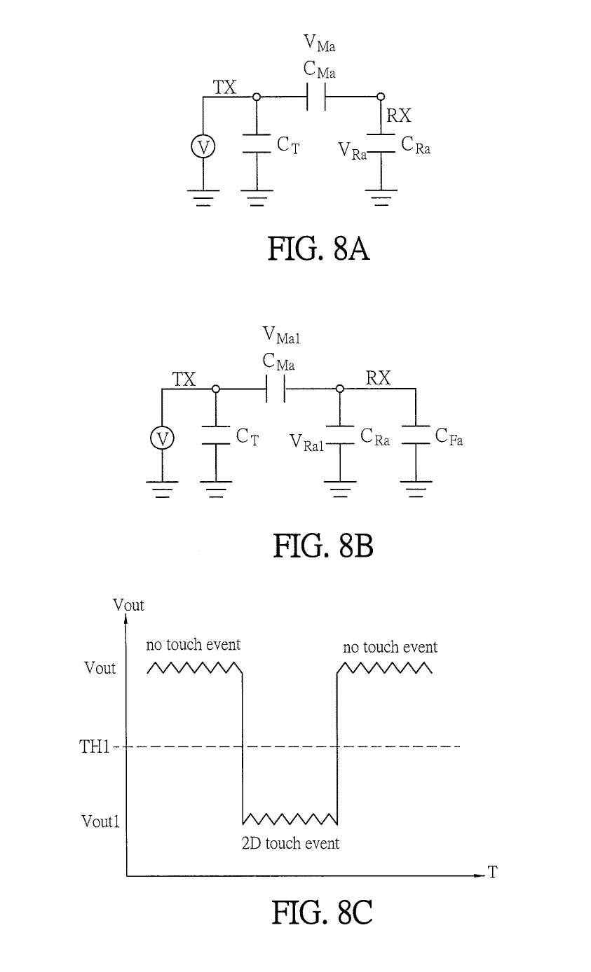

FIG. 8A is a schematic diagram of the control circuit of the touch display device of the disclosure when the 2D and 3D touch events are sensed by different sensing electrodes in the situation of no touch event, and FIG. 8B is a schematic diagram of the control circuit of the touch display device of the disclosure when the 2D and 3D touch events are sensed by different sensing electrodes in the situation of having 2D touch event. Herein, the horizontal sensing electrode R-XY senses the touch in the horizontal direction, and the vertical sensing electrode R-Z senses the touch in the vertical direction. The sensing electrodes are not integrated. FIG. 8C is a schematic diagram showing the waveform of the touch signal Vout in the situations of no touch event and having 2D touch event.

As shown in FIG. 8A, the touch signal Vout in the situation of no touch event can be obtained as follow:

$$V = {V}_{Ma} + {V}_{Ra}$$

$${V}_{Ra} = \frac{{C}_{Ma}}{{C}_{Ra} + {C}_{Ma}} \times V = xV$$

$${V}_{Ma} = \frac{{C}_{Ra}}{{C}_{Ra} + {C}_{Ma}} \times V = yV$$

$${V}_{out} = {V}_{Ra} \times n$$

As shown in FIG. 8B, the touch signal Vout in the situation of having 2D touch event can be obtained as follow:

$$V = {V}_{Ma 1} + {V}_{Ra 1}$$

$${V}_{Ra 1} = \frac{{C}_{Ma}}{{C}_{Ra} + {C}_{Ma} + {C}_{Fa}} \times V = {x}_{1} V$$

$${V}_{Ma 1} = \frac{{C}_{Ra} + {C}_{Fa}}{{C}_{Ra} + {C}_{Ma} + {C}_{Fa}} \times V = {y}_{1} V$$

$${V}_{out 1} = {V}_{Ra 1} \times n$$

In this embodiment, as shown in FIG. 8C, the touch signal voltage threshold value for a 2D touch event is TH1. When the touch detecting circuit 15 detects the touch signal Vout1 and determines that its voltage is lower than the voltage threshold value TH1, the touch event is detected as a 2D touch event so as to generate the corresponding control operation.

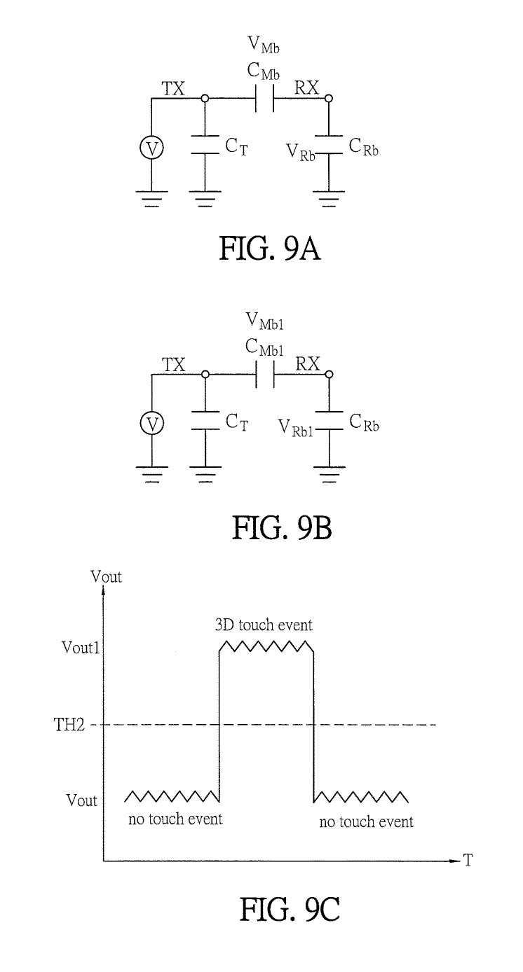

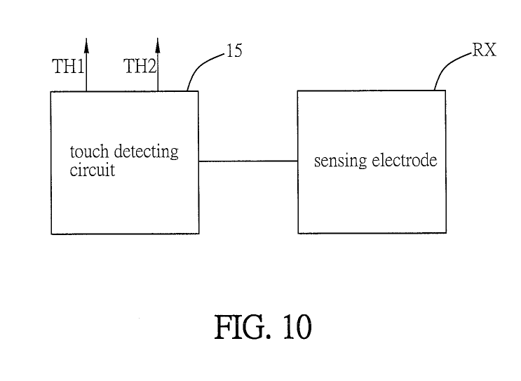

FIG. 9A is a schematic diagram of the control circuit of the touch display device of the disclosure when the 2D and 3D touch events are sensed by different sensing electrodes in the situation of no touch event, and FIG. 9B is a schematic diagram of the control circuit of the touch display device of the disclosure when the 2D and 3D touch events are sensed by different sensing electrodes in the situation of having a touch event in vertical direction. Herein, the horizontal sensing electrode R-XY senses the touch in the horizontal direction, and the vertical sensing electrode R-Z senses the touch in the vertical direction. The sensing electrodes are not integrated. FIG. 9C is a schematic diagram showing the waveform of the touch signal Vout in the situations of no touch event and having a touch event in vertical direction.

As shown in FIG. 9A, the touch signal Vout in the situation of no touch event can be obtained as follow:

$$V = {V}_{M} + {V}_{R}$$

$${V}_{Rb} = \frac{{C}_{Mb}}{{C}_{Rb} + {C}_{Mb}} \times V = xV$$

$${V}_{Mb} = \frac{{C}_{Rb}}{{C}_{Rb} + {C}_{Mb}} \times V = yV$$

$${V}_{out} = {V}_{Rb} \times n$$

As shown in FIG. 9B, the touch signal Vout1 in the situation of having a touch event in vertical direction can be obtained as follow:

$$V = {V}_{M} + {V}_{R}$$

$${V}_{Rb 1} = \frac{{C}_{Mb 1}}{{C}_{Rb} + {C}_{Mb 1}} \times V = {x}_{1} V$$

$${V}_{Mb 1} = \frac{{C}_{Rb}}{{C}_{Rb} + {C}_{Mb 1}} \times V = {y}_{1} V$$

$${V}_{out 1} = {V}_{Rb 1} \times n$$

In this embodiment, as shown in FIG. 9C, the touch signal voltage threshold value for a 3D touch event is TH2. When the touch detecting circuit 15 detects the touch signal Vout1 and determines that its voltage is greater than the voltage threshold value TH2, the touch event is detected as a 3D touch event so as to generate the corresponding control operation.

In some embodiments, the driving mode of the touch display device can be a full-time driving mode or a part-time driving mode. In the full-time driving mode, the transmission electrode TX is applied with a plurality of, for example, pulse signals (named as driving signal in the following description) within a frame time, and the sensing electrode obtains the sensing signal of the variation of the mutual capacitance. In the part-time driving mode, each frame time includes a display period and a sensing period. During the sensing period, the driving signals are sent to the transmission electrode TX, and the sensing electrode receives the sensing signals.

In some embodiments, during the sensing period in the part-time driving mode, the driving signals (e.g. the pulse signals) are corresponding to and identical to the signal of the first power source VDD (see FIG. 1B). In more detailed, the pulse signals sent to the transmission electrode TX and the pulse signal of the first power source VDD are transmitted at the same time, and the pulse size (voltage difference) thereof are the same. In other words, the signal of the first power source VDD changes based on the variation of the driving signals sent to the transmission electrode TX. The reason of this configuration is that the current flowing through the light-emitting element 12 may be changed, which will affect the lighting effect if only transmitting the driving signal to the transmission electrode TX. Accordingly, the waveform of the pulse signal of the first power source VDD is corresponding to and identical to the waveform of the driving signal transmitted to the transmission electrode TX so as to decrease the interference of the change of the current flowing through the light-emitting element 12. Thus, the driving signal sent to the transmission electrode TX cannot affect the lighting effect of the light-emitting element 12. In another embodiment, during the sensing period, the waveform of the scan signal transmitted to the scan line SL and the waveform of the data signal transmitted to the data line are corresponding to and identical to the waveforms of the driving signal, the signal of the first power source VDD, and the signal of the second power source VSS. This configuration can prevent the overloading of the touch control electrode so as to maintain the touch control quality of the touch display device. In some embodiments, the driving transistor T2 can be controlled in a cutoff status during the sensing period, so that the light-emitting element 12 does not emit light during this period. In this case, the driving signal transmitted during the sensing period cannot affect the lighting of the light-emitting element 12. Alternatively, the light-emitting element 12 is applied with a reverse bias and is thus not lighting, thereby preventing the undesired interference of the lighting effect of the light-emitting element 12. Otherwise, the first power source VDD or the second power source VSS can be floated to achieve the above effect, and this disclosure is not limited.

To be noted, the threshold voltage (Vth) of the transistor may have shift during the full-time driving mode or the part-time driving mode due to the factors of different manufacturing processes, materials or component characteristics of the driving transistors of the touch display device. In this case, the driving currents of the pixel structures may have slight differences when applying the same data voltage, so that the display image of the touch display device will have non-uniform brightness, which may cause the mura effect. In order to improve the above issue, in some embodiments, a pixel compensating circuit is provided to compensate the non-uniform brightness caused by the shift of the threshold voltage (Vth) of the driving transistor. For example, a 6T1C pixel circuit is provided to control and compensate the non-uniform brightness caused by the shift of the threshold voltage (Vth) of the driving transistor T2.

As mentioned above, in the touch display device of the disclosure, the 2D or 3D touch control electrode can be integrated in the touch panel, and the additional touch panel is not needed. In addition, the circuit for controlling the touch function and the circuit for controlling the display function can be integrated in the same control IC, thereby reducing the processes for manufacturing the touch display device and the cost of the control IC.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A touch display device, comprising:
a touch panel comprising:
a thin-film transistor (TFT) substrate;
a light-emitting element disposed on the TFT substrate and having a first end electrode, a light-emitting layer and a second end electrode, wherein the second end electrode is disposed on the first end electrode, and the light-emitting layer is disposed between the first end electrode and the second end electrode;
a transmission electrode and a sensing electrode disposed on the light-emitting layer respectively;
a cover layer disposed opposite to the TFT substrate; and
an encapsulation layer disposed between the second end electrode and the cover layer.

2. The touch display device of claim 1, wherein the encapsulation layer is a compressible layer.

3. The touch display device of claim 2, wherein the encapsulation layer is filled with gas or comprises an organic material, an inorganic material, an adhesive material, or combination thereof

4. The touch display device of claim 1, wherein at least one of the transmission electrode and the sensing electrode is disposed between the second end electrode and the encapsulation layer.

5. The touch display device of claim 1, wherein the sensing electrode senses a three-dimensional touch signal.

6. The touch display device of claim 5, wherein the sensing electrode comprises a horizontal sensing electrode and a vertical sensing electrode.

7. The touch display device of claim 6, wherein at least one of the transmission electrode, the horizontal sensing electrode and the vertical sensing electrode is disposed at an inner side or an outer side of the cover layer.

8. The touch display device of claim 6, wherein at least one of the transmission electrode, the horizontal sensing electrode and the vertical sensing electrode is disposed between the second end electrode and the encapsulation layer.

9. The touch display device of claim 6, wherein at least one of the transmission electrode, the horizontal sensing electrode and the vertical sensing electrode is functioned as the second end electrode.

10. The touch display device of claim 6, wherein one of the transmission electrode and the vertical sensing electrode is disposed at an inner side or an outer side of the cover layer, and another one of the transmission electrode and the vertical sensing electrode is functioned as the second end electrode.

11. The touch display device of claim 5, wherein the sensing electrode comprises a three-dimensional sensing signal.

12. The touch display device of claim 11, wherein at least one of the transmission electrode and the three-dimensional sensing electrode is disposed at an inner side or an outer side of the cover layer.

13. The touch display device of claim 11, wherein at least one of the transmission electrode and the three-dimensional sensing electrode is disposed between the second end electrode and the encapsulation layer.

14. The touch display device of claim 11, wherein at least one of the transmission electrode and the three-dimensional sensing electrode is functioned as the second end electrode.

15. The touch display device of claim 11, wherein one of the transmission electrode and the three-dimensional sensing electrode is disposed at an inner side or an outer side of the cover layer, and another one of the transmission electrode and the three-dimensional sensing electrode is functioned as the second end electrode.

16. The touch display device of claim 5, further comprising:
a reference electrode disposed at an inner side or an outer side of the cover layer or at a side of the TFT substrate away from the light-emitting element.

17. The touch display device of claim 16, wherein the reference electrode is a patterned electrode.

18. The touch display device of claim 5, further comprising:
a touch detecting circuit electrically connected with the sensing electrode, wherein the touch detecting circuit provides a horizontal touch voltage threshold value and a vertical touch voltage threshold value, and the horizontal touch voltage threshold value is different from the vertical touch voltage threshold value.

19. The touch display device of claim 18, wherein a control circuit determines a touch signal is a two-dimensional touch event or a three-dimensional touch event based on a comparison result of a voltage value of the touch signal detected by the touch detecting circuit, the horizontal touch voltage threshold value and the vertical touch voltage threshold value.

20. The touch display device of claim 1, wherein a driving mode of the touch display device is a full-time driving mode or a part-time driving mode.
